(19) United States
(12) Patent Application Publication
(10) Pub. No.: US 2026/0092357 A1
(43) Pub. Date: Apr. 2, 2026

(54) MONOLITHIC PHYSICAL VAPOR DEPOSITION TARGET DESIGN

(71) Applicant: Applied Materials, Inc., Santa Clara, CA (US)

(72) Inventors: Madan Kumar SHIMOGA MYLARAPPA, Bangalore (IN); Jiao SONG, SG (SG); Kirankumar Neelasandra SAVANDAIAH, Bangalore (IN); Zheng Min CLARENCE CHONG, SG (SG); Xiangli FU, SG (SG)

(21) Appl. No.: 18/904,644

(22) Filed: Oct. 2, 2024

(51) Int. Cl. C23C 14/34

(52) U.S. Cl. CPC C23C 14/3407

(57) ABSTRACT

In one embodiment, a physical vapor deposition (PVD) target is provided. The PVD target includes a body having a target region and a backing region. The backing region includes a diameter greater than the diameter of the target region. The target region and backing region have the same coefficient of thermal expansion and the same material.

### BACKGROUND

### Field

Embodiments of the present subject matter generally relates to physical vapor deposition. More particularly, the subject matter relates to a sputtering target for use in a physical vapor deposition chamber and process.

### Description of the Related Art

Physical Vapor Deposition (PVD) is a crucial thin-film deposition technique extensively employed in semiconductor substrate processing to create thin layers of materials with enhanced properties. PVD operates under vacuum conditions and involves the evaporation or sputtering of target materials, such as metals or ceramics, onto a semiconductor substrate to form thin films. In sputtering, high-energy ions bombard the target material of the target assembly, dislodging atoms from a target that are then deposited onto the substrate. PVD is highly versatile, allowing for precise control over film thickness, uniformity, and composition, making it ideal for fabricating various semiconductor components, including integrated circuits, microelectromechanical systems (MEMS), and optical coatings. The deposited thin films provide essential functionalities, such as conductive layers for interconnections and diffusion barriers, and contribute to enhancing device performance, reliability, and miniaturization in modern semiconductor manufacturing processes.

The choice of target material is critical as it directly determines the properties and characteristics of the thin film being deposited. Different applications require different materials with specific properties. For example, semiconductor devices may require thin films made of metals like aluminum, molybdenum, copper, or tungsten for interconnects and thermal management, or dielectric materials like silicon dioxide or silicon nitride for insulating layers. Other specialized applications may demand exotic materials like magnetic alloys or refractory compounds. In all target material choices, throughput and target life are always a key consideration when reviewing a manufacturing process.

To ensure high-quality thin films, the target material must be pure and have a uniform composition. The design of a target assembly can be qualified using metrics that include the erosion profiles of the target during sputtering, target crystallographic texture, substrate to target distance, and the gas scattering factor during the deposition process. The design of a target assembly, target life span, the shape and size of the target material, and the corresponding relations all influence the deposition process, as they influence the distribution, thickness of the deposited thin film on the substrate, and service life of the target assembly.

Therefore, there exists a need in the art for a sputtering target apparatus with an improved life span.

### SUMMARY

In one embodiment, a physical vapor deposition (PVD) target is provided. The PVD target includes a body having a target region and a backing region. The backing region includes a diameter greater than the diameter of the target region. The target region and backing region have the same coefficient of thermal expansion and the same material.

In another embodiment, a physical vapor deposition (PVD) processing system is provided. The PVD processing system, includes a chamber body, a substrate support disposed within the chamber body, and a deposition assembly disposed opposite the substrate support. The deposition assembly includes a magnetron, and a target mounted to the magnetron. The target includes a body, the body being monolithic. The body includes a backing region, mounted to the magnetron, and a target region disposed opposite the magnetron. The target region and backing region both includes a grain size of 5 microns or smaller.

In yet another embodiment, a physical vapor deposition (PVD) processing system is provided. The PVD processing system, includes a chamber body, a substrate support disposed within the chamber body, and a deposition assembly disposed opposite the substrate support. The deposition assembly includes a magnetron, and a target mounted to the magnetron. The target includes a body, the body being monolithic. The body includes a thickness of about 1 inch, a backing region, mounted to the magnetron, and a target region disposed opposite the magnetron. The target region and backing region include at least 99% copper and a grain size of 5 microns or smaller.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic view of a physical vapor deposition processing system.

FIG. 2 is schematic, cross-sectional view of a target according to some embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of target assemblies for use in substrate processing chambers, such as for a physical vapor deposition (PVD) system, are provided herein.

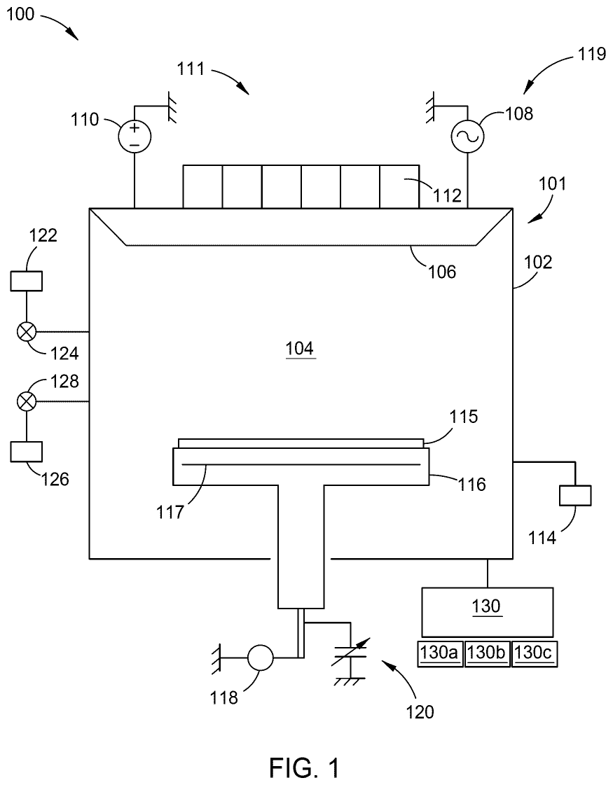

FIG. 1 illustrates a schematic view of a PVD system 100, according to some embodiments. The PVD system 100 includes a chamber 101. The PVD system 100 may be used to perform the methods described herein. The chamber 101 is a PVD chamber. It is to be understood that the chamber 101 is an exemplary PVD chamber and other PVD chambers may be used with the target assemblies described herein.

The chamber 101 includes a chamber body 102 having chamber walls that define a processing volume 104. The chamber 101 further includes a target 106 and a substrate support 116, disposed within the processing volume 104. The target 106 is described in more detail below.

The substrate support 116 is operable to secure (e.g., chuck) a substrate 115 to the substrate support 116. The substrate 115 is disposed within the processing volume 104 during substrate processing operations. In some embodiments, the substrate support 116 includes an electrode 117 to chuck the substrate 115. In other embodiments the substrate support 116 uses vacuum to chuck the substrate 115.

The PVD system 100 further includes a deposition assembly 119 disposed opposite the substrate support 116. The deposition assembly 119 includes an RF power supply 108, a vacuum source 114, a controller 130, an auto capacitance tuner 120, a power source 118, a reactive gas source 126, a sputter gas source 122, a DC power supply 110, and a magnetron 111.

The target 106 is mounted to the magnetron 111 and can be coupled to the RF power supply 108 and the DC power supply 110. Power provided from RF power supply 108 and/or the DC power supply 110 to the target 106 can be used to ignite a plasma in the processing volume 104. The plasma is formed by a sputter gas. For example, the sputter gas may be argon (Ar), oxygen (O), hydrogen (H), fluorine (F), chlorine (CI), or any combination thereof. Other reactive gases are also contemplated. The plasma may be created in the processing volume 104 by a capacitive process, an inductive process, or other plasma generation methods.

The magnetron 111 is disposed the above the substrate support 116. The magnetron 111 directs magnetic fields within the processing volume 104 to regions around the target 106 in the processing volume 104. These magnetic fields can help increase a density of the plasma formed in the processing volume 104 around the target 106. In one embodiment, the magnetron 111 can include one or more magnets 112 (e.g., strength magnets). The one or more magnets 112 may be arranged to provide a magnetic field which extends through the target 106 and into the processing volume 104. In some embodiments, the generated magnetic fields can trap electrons along magnetic field lines to increase the plasma ion density by enabling additional electron-gas atom collisions. The magnetron 111 and the magnets 112 are adjustable to adjust the magnetic field within the process volume 104.

The vacuum source 114 is fluidly coupled to the processing volume 104. As described herein, fluidly coupled includes translation of fluid between the described elements. For example, the vacuum source 114 is able to create a vacuum environment within the processing volume. A vacuum environment includes a pressure of 1 atmosphere or less. The vacuum source 114 is any device or assembly which may create a vacuum. For example, the vacuum source 114 is a vacuum pump. The vacuum source 114 maintains the processing volume 104 at a specified process pressure during processing operations. The vacuum source 114 also evacuates sputter gases, reactive gases, and other gases from the processing volume 104.

The power source 118 is coupled to the electrode 117 in the substrate support 116. The electrode 117 induces an electrical bias on the substrate 115. The power source 118 may be a RF or DC power source. In some embodiments, a self-bias may form on the substrate 115 during processing. In some embodiments, the electrode 117 may be coupled to the auto capacitance tuner 120. The auto capacitance tuner 120 is operable to adjust the capacitance (and thus impedance) from the substrate support 116 to a ground.

The reactive gas source 126 is fluidly connected to the processing volume 104. A reactive gas flow controller 128, such as a mass flow controller (MFC), may be disposed between a reactive gas source 126 and the process volume 104. The reactive gas flow controller 128 controls a flow of the reactive gas (e.g., oxygen) from the reactive gas source 126 to the processing volume 104.

The sputter gas source 122 is fluidly coupled to the processing volume 104. A sputter gas flow controller 124, such as an MFC, may be disposed between the sputter gas source 122 and the processing volume 104. The sputter gas flow controller 124 controls a flow of the sputter gas (e.g., argon) from the sputter gas source 122 to the processing volume 104.

The chamber 101 further includes a controller 130. The controller 130 includes a programmable central processing unit (CPU) 130a which is operable with a memory 130b (e.g., non-volatile memory) and support circuits 130c. The support circuits are conventionally coupled to the CPU and comprise cache, clock circuits, input/output subsystems, power supplies, and the like, and combinations thereof coupled to the various components of PVD system 100, to facilitate control thereof. The CPU 130a is one of any form of general purpose computer processor used in an industrial setting, such as a programmable logic controller (PLC), for controlling various components and sub-processors of the processing system. The memory 130b, coupled to the CPU 130a, is non-transitory and is typically one or more of readily available memories such as random access memory (RAM), read only memory (ROM), floppy disk drive, hard disk, or any other form of digital storage, local or remote.

Typically, the memory 130b is in the form of a non-transitory computer-readable storage media containing instructions (e.g., non-volatile memory), which when executed by the CPU 130a, facilitates the operation of PVD system 100. The instructions in the memory 130b are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 130 may be used with one or any combination of the various systems described herein.

As used herein, ‘a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “memory,” “at least one memory,” or “one or more memories” generally refers to a single memory configured to store data and/or instructions, or multiple memories configured to collectively store data and/or instructions.

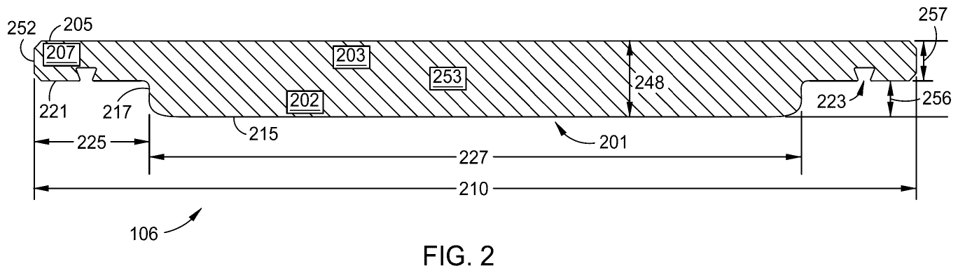

FIG. 2 is a schematic, cross-sectional view illustrating the target 106, according to some embodiments. The target 106 is a single monolithic body. Monolithic as described herein includes a body of a uniform material, a body formed from a single part, a uniform distribution of material within the body, or any combination thereof. In some embodiments, the target 106 is a monolithic copper PVD target. In some embodiments, the target 106 is a monolithic copper and manganese PVD target. According to some embodiments, the target 106 is manufactured from a solid body. In other embodiments, one or more layers are joined together, e.g., hot isostatic pressed together to form the target 106. In other embodiments, the target 106 is formed through an additive manufacturing process that forms a body with a uniform grain structure throughout the body. Exemplary additive manufacturing processes include powder bed fusion, binder jetting, direct energy deposition, bound powder extrusion, but other processes are contemplated.

The target 106 material includes copper according to some embodiments. for example, in some embodiments the target 106 material includes at least 90% copper, such as 95% copper by atomic weight or greater, such as 98% copper by atomic weight or greater. In some embodiments, the target 106 material includes are least 90% copper (Cu) by atomic weight or greater, at least 0.1% manganese (Mn) by atomic weight or greater, and trace amounts of other elements, such as 95% or greater Cu by atomic weight and 0.5% or greater Mn by atomic weight, such as 99% or greater Cu by atomic weight and 1% or greater Mn by atomic weight. In other embodiments, the target material of the target 106 is pure copper that has a metal purity of greater than 99%, such as greater than 99.99%, or greater than 99.999%, or even greater than 99.9999%. In some embodiments the target 106 material is native copper. Native copper as described herein refers to copper free of oxygen, copper having less than trace amounts of oxygen, or oxygen concentration of less than 0.1%.

The target 106 has a coefficient of thermal conductivity (CTC) between about 360 (Watt/m K°) and about 420 (Watt/m K°), such as between about 380 (Watt/m K°) and about 400 (Watt/m K°), for example about 390 (Watt/m K°). The target 106 has a target metal grain size of 5 microns or smaller, such as a target metal grain size of 2 microns or smaller, for example a grain size of 1 micron or smaller. The grain size is an estimate of the average grain diameter. The target 106 includes a density of about 8.8 grams per cubic centimeter to about 9 grams per cubic centimeters, for example about 8.9 grams per cubic centimeter. The target 106 includes a resistivity of about 1.5 micro-ohm-meters to about 2 micro-ohm-meters, for example, about 1.7 micro-ohm-meters. The target 106 includes a modulus of elasticity of about 105 gigapascals (GPa) to about 145 GPa, for example, about 115 GPa to about 135 Gpa, such as about 123 GPa. During operation, traditional target assemblies with a target and backing plate experiences internal stresses because the vacuum in the process region pulls the target inward, while the backing plate heats up and bows away from the process region. The opposing forces cause the backing plate to pull the target opposite the vacuum and introduce internal stresses that reduce target material lifespan. The monolithic and smaller grain size aspects described herein reduce bowing of the target 106 when compared to target assemblies that incorporate a backing plate between the magnetron 112 (FIG. 1) and the target 106. The reduction in grain size increases the strength of the target 106. The use of a single solid body, as opposed to two bodies, further enhances the target's 106 ability to resist bowing caused by a mismatch of coefficient of thermal expansions between two bodies. The monolithic target further enables additional space adjustment between magnetic components of the magnetron 112 and the target for enhanced and increased operational time and deposition uniformity.

By having a target 106 as described herein a target life of at least 80 kilo watt hours and greater is achievable. For example, when using magnets 112 with a maximum energy product of 9 mega gauss oersteds (MGOe) or greater in the magnetron 111, the monolithic construction of the target 106 allows for extended target life of 100 kilo watt hours, 200 kilo watt hours, 300 kilo watt hours or greater and reduces bowing of the target toward the magnetron 111 caused by a mismatch of coefficient of thermal expansion (CTE) within the target and the backing plate materials of conventional targets assemblies.

The target 106 includes a body 201 having a target region 202 and a backing region 203. The body 201 is a circular body. In some embodiments, the body 201 is a triangular body, a rectangular body, a trapezoidal body, or any combination thereof. The target region 202 and the backing region 203 form the monolithic target 106 of the same material.

In some embodiments, the target region 202 and the backing region 203 have the same coefficient of thermal expansion such that the body 201 of the target 106 has uniform coefficient of thermal expansion. In some embodiments the CTE is about 15.5 parts per million per Kelvin (ppm/K) to about 17.5 ppm/K, for example, about 16.8 ppm/K.

The body thickness 248 of the target 106 is configured to bow less than 10 millimeters towards the magnetron 111 during a deposition operation, such as configured to bow less than 4 millimeters towards the magnetron 111, such as configured to bow less than 1 millimeters towards the magnetron 111. The monolithic target with reduced grain size described herein reduces the bowing caused by the mismatch of CTE of the backing plate material and target material, while providing more space for magnet to target space tuning. For example, when using strong magnets, the target 106 bows 2 millimeter or less towards the magnets, for example, the target 106 bows 0.6 millimeters or less.

The backing region 203 includes a mounting region 207, a mounting face 205, a diameter 210, a channel 223, and a support region 253. The mounting region 207 is disposed radially outward of the support region 253. The mounting region 207 includes an upper face 221, the mounting face 205, an outer face 252, the channel 223, an extension length 225, and mounting thickness 257.

The outer face 252 is the radially outward face of the target 106 and defines the diameter 210 of the target 106. The outer face 252 diameter 210 is between about 15 inches and about 48 inches. For example, between about 20 inches and about 21 inches. For example, about 20.5 inches.

The extension length 225 is the distance between sidewalls 217 of the support region 253 and the outer face 252. The extension length 225 is about 2 inches to about 4 inches, for example about 3 inches.

The mounting thickness 257 is the distance between the upper face 221 and mounting face 205. The mounting thickness 257 is about 0.48 inches to about 0.52 inches, for example about 0.5 inches.

The mounting face 205 includes elements to mount the target 106 to the magnetron 111. The elements of the mounting face 205 include one or more apertures, threaded holes, or other types of geometry (not shown) to affix the target to the magnetron 111. In some embodiments, the mounting face 205 is a copper surface in contact with the magnetron 112 (FIG. 1). The copper surface is a surface comprising about 90% or more copper.

The channel 223 is formed within the upper face 221 of the mounting region 207. In some embodiments, the channel 223 is disposed radially outward of the sidewalls 217 of the support region 253. For example, the channel 223 is disposed between about 1 inch and about 2 inches radially outward from the sidewalls 217 of the support region 253. In some embodiments the channel 223 includes a dovetail geometry. The dovetail geometry enables a seal, such as an O-ring, to be disposed therein. The channel 223 is described in more detail below.

The target region 202 includes a body thickness 248, the support region 253 and is disposed radially inward of the mounting region 207. The support region 253 includes, a target region diameter 227, sidewalls 217, and a process face 215.

The body thickness 248 is defined by the distance between the process face 215 and the mounting face 205. The body thickness 248 is less than 1.1 inches, for example, the body thickness 248 is about 0.95 inches to about 1.05 inches. For example, the body thickness 248 is about 1 inch. In other embodiments, the body thickness 248 varies radially from the center of the process face 215 to the sidewalls 217. Reducing the thickness of the body allows for more tuning with the spacing between magnets 112 and the target 106.

The process face 215 defines the target region 202 and partially defines the support region 253. The process face 215 includes a flat surface parallel to the mounting face 205. When the target 106 is placed in a process chamber, the process face 215 faces the substrate. The process face 215 includes a diameter. In some embodiments, the process face diameter is the same as the target region diameter 227. The target region diameter 227 is defined as the diameter formed by the sidewalls 217. The target region diameter 227 is about 17 inches to about 18 inches, for example about 17.5 inches.

The target region 202 includes a thickness 256 between the process face 215 and upper face 221. The thickness 256 is about 0.4 inches to about 0.6 inches. The thickness 256 is the thickness of the target region 202.

If the thickness 256 is too large, extra energy must be applied by the system to achieve a specific plasma density in the process volume. If the thickness 256 is too small, the target 106 experiences too much deflection that can lead to non-uniform erosion patterns and a reduction in the useful life of the target 106. In some embodiments, the thickness 256 is about 48% to about 52% of the body thickness 248. For example, the thickness 256 is about 50% of the body thickness 248.

It is contemplated that one or more aspects disclosed herein may be combined. As an example, one or more aspects, features, components, operations and/or properties of the PVD system 100 and target 106, may be combined.

Benefits of the present disclosure include increased target life, reduced target bowing, improved target strength, and greater tuning ability. As an example, by ensuring a uniform CTE, the target expansion is not affected by a backing plate with different CTE.

When the word “approximately” or “about” are used herein to denote a variance in value of up to ±10%, of up to 5%, of up to 2%, of up to 1%, of up to 0.5%, of up to 0.1%, or up to 0.01%.

While the foregoing is directed to embodiments of the present disclosure, other and further embodiments of the disclosure may be devised without departing from the basic scope thereof, and the scope thereof is determined by the claims that follow.

1. A physical vapor deposition (PVD) target, comprising:
a body comprising:
a target region; and
a backing region comprising a diameter greater than a diameter of the target region, both the target region and the backing region consisting of:
a same coefficient of thermal expansion; and
copper, wherein the copper comprises a grain size of 5 microns or smaller.

2. The PVD target of claim 1, wherein the target region and the backing region form a monolithic target.

3-5. (canceled)

6. The PVD target of claim 1, wherein the body comprises a thickness of less than 1.1 inches.

7. The PVD target of claim 1, wherein the copper comprises a grain size of 1 microns or smaller.

8. (canceled)

9. The PVD target of claim 1, wherein the copper comprises a purity of 99.99% or greater.

10. A physical vapor deposition (PVD) processing system, comprising:
a chamber body;
a substrate support disposed within the chamber body; and
a deposition assembly disposed opposite the substrate support, the deposition assembly comprising:
a magnetron; and
a target mounted to the magnetron, the target comprising:
a body, the body consisting of a monolithic copper target with a grain size of 5 microns or smaller, the body comprising:
a backing region, mounted to the magnetron; and
a target region disposed opposite the magnetron, the target region and backing region both comprising.

11-13. (canceled)

14. The PVD processing system of claim 10, wherein the body is circular.

15. A physical vapor deposition (PVD) processing system, comprising:
a chamber body;
a substrate support disposed within the chamber body; and
a deposition assembly disposed opposite the substrate support, the deposition assembly comprising:
a magnetron; and
a target mounted to the magnetron, the target comprising:
a body, the body being monolithic, the body comprising:
a mounting face comprising a copper surface in contact with the magnetron;
a thickness of about 1 inch;
a backing region, mounted to the magnetron; and
a target region disposed opposite the magnetron, the target region and backing region consisting of copper, wherein the copper comprises a grain size of 5 microns or smaller.

16. The PVD processing system of claim 15, wherein the target is configured to bow less than 0.7 millimeters towards the magnetron during a deposition operation.

17. The PVD processing system of claim 15, wherein the target has a target life of at least 80 kilowatt hours.

18. The PVD processing system of claim 15, wherein the target comprises a density of about 8.8 grams per cubic centimeter to about 9 grams per cubic centimeters.

19. The PVD processing system of claim 15, wherein the thickness is defined as a distance between a process face of the target region and a mounting face of the backing region.

20. The PVD processing system of claim 15, wherein the target comprises a resistivity of 2 micro-ohms or less.
